(19) United States
(12) Patent Application Publication
(10) Pub. No.: US 2010/0302718 A1
(43) Pub. Date: Dec. 2, 2010

(54) ELECTRONIC DEVICE, HOUSING, AND GASKET

(75) Inventors: Takao Shinoda, Kawasaki (JP); Kohei Choraku, Kawasaki (JP); Yasuhiro Ite, Kawasaki (JP); Shingo Yamaguchi, Kawasaki (JP); Satoshi Watanabe, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/785,831

(22) Filed: May 24, 2010

(30) Foreign Application Priority Data
May 29, 2009 (JP) 2009-131233

(51) Int. Cl. F16J 15/06; H05K 5/00

(52) U.S. Cl. 361/679.01; 277/630

(57) ABSTRACT

An electronic device includes: a first case and a second case; a gasket sandwiched between the first case and the second case, the gasket having an elasticity and being formed on the edge of the first case; and an electronic component accommodated in the first and second cases; wherein the gasket has a first side surface facing inward and a second side surface facing outward, and the first side surface has a first angle with respect to an imaginary line which is perpendicular to a direction in which the first case is joined to the second case, the second side surface has the second angle with respect to an imaginary line which is perpendicular to a direction in which the first case is joined to the second case, and the first angle is different from the second angle when the first case is disjoined to the second case.

### CROSS-REFERENCE TO RELATED APPLICATION

This application is based upon and claims the benefit of priority of the prior Japanese Patent Application No. 2009-131233, filed on May 29, 2009, the entire contents of which are incorporated herein by reference.

### FIELD

A certain aspect of the embodiments discussed herein relates to an electronic device, a housing, and a gasket.

### BACKGROUND

A gasket is provided that prevents water from entering through the gap between a first case and a second case. The gasket is elastic, and is disposed in a groove that is provided in one of the first and second cases. The gasket is pressed by the other of the first and second cases, and water-tightness is thereby provided between the first and second cases.

[Patent Document] Japanese Laid-open Patent Publication No. 2008-218633 describes an example of the related art.

The gasket is disposed in the groove and thereafter the first and second cases are joined together. There is a risk of the gasket becoming skewed from the desired position when the first and second cases are joined. In that case, there is a risk that the water-tightness provided by the gasket will be degraded. If care has to be taken to maintain the position of the gasket when joining the first and second cases, there is a risk of the efficiency with which the joining operation is performed becoming degraded.

### SUMMARY

According to an aspect of an embodiment, an electronic device includes: a first case and a second case; a gasket sandwiched between the first case and the second case, the gasket having an elasticity and being formed on the edge of the first case; and an electronic component accommodated in the first and second cases; wherein the gasket has a first side surface facing inward and a second side surface facing outward, and the first side surface has a first angle with respect to an imaginary line which is perpendicular to a direction in which the first case is joined to the second case, the second side surface has the second angle with respect to an imaginary line which is perpendicular to a direction in which the first case is joined to the second case, and the first angle is different from the second angle when the first case is disjoined to the second case.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is an exploded perspective view of a cellular phone;

FIG. 2A is a view of a front case;

FIG. 2B is a view of a rear case;

FIG. 3A is a sectional view along a line IIIA-IIIA in FIG. 2B;

FIG. 3B is a view of the portion shown in FIG. 3A when the rear case and the front case have been joined;

FIGS. 4A and 4B are views illustrating a first modification; and

FIGS. 4C and 4D are views illustrating a second modification.

### DESCRIPTION OF EMBODIMENTS

A cellular phone will be described as an example of an electronic device.

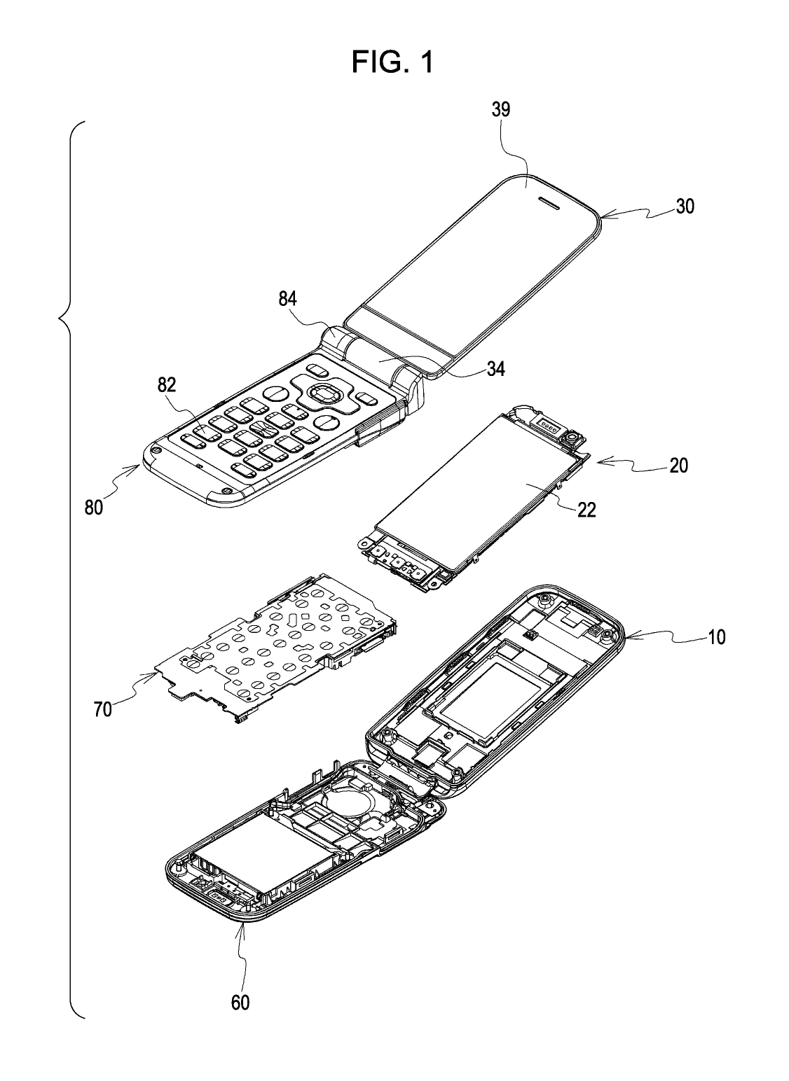

FIG. 1 is an exploded perspective view of a cellular phone. The cellular phone includes rear cases 10 and 60, a display unit 20, front cases 30 and 80, and a printed circuit board 70. The display unit 20 has a display 22. The display unit 20 is housed in the rear case 10 and the front case 30. A plurality of keys 82 are provided on the front case 80. The printed circuit board 70 is housed in the rear case 60 and the front case 80. Contacts that are switched on and off in response to operation of the keys 82 are provided on the printed circuit board 70. The front cases 30 and 80 have hinge portions 34 and 84, respectively. The front cases 30 and 80 are pivotably coupled through the hinge portions 34 and 84. The display unit 20 and the printed circuit board 70 are electronic components.

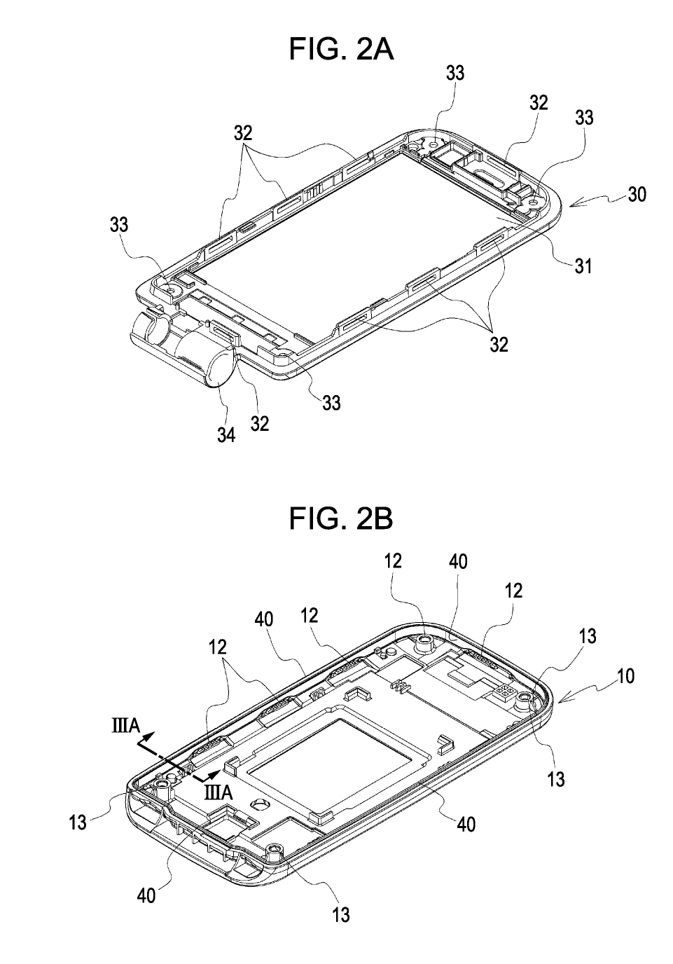

FIGS. 2A and 2B are views of the front case 30 and the rear case 10, respectively. In FIG. 1, a front panel 39 is fixed to the front side of the front case 30. The front case 30 has an opening 31 through which the display 22 is exposed. A plurality of engagement holes 32 and through-holes 33 are formed around the opening 31. A plurality of engagement portions 12 that engage in the engagement holes 32 are formed on the rear case 10. Also, a plurality of screw holes 13 that correspond to the through-holes 33 are formed in the rear case 10. The rear case 10 and the front case 30 are joined to each other with the display unit 20 therebetween, so that the display unit 20 is housed in the rear case 10 and the front case 30. The rear case 10 and the front case 30 are made of a synthetic resin.

A gasket 40 is molded together with the rear case 10, and is thereby bonded to the rear case 10. The gasket 40 is elastic, and is for example made of a thermoplastic elastomer. That is, the rear case 10 and the gasket 40 are made of different materials and molded together. The gasket 40 is in the form of a continuous ring that extents along the rim of the rear case 10. When the rear case 10 and the front case 30 are joined, the gasket 40 is sandwiched therebetween. The gasket 40 functions to waterproof the space inside the rear case 10 and the front case 30. The gasket 40 will be described in more detail below.

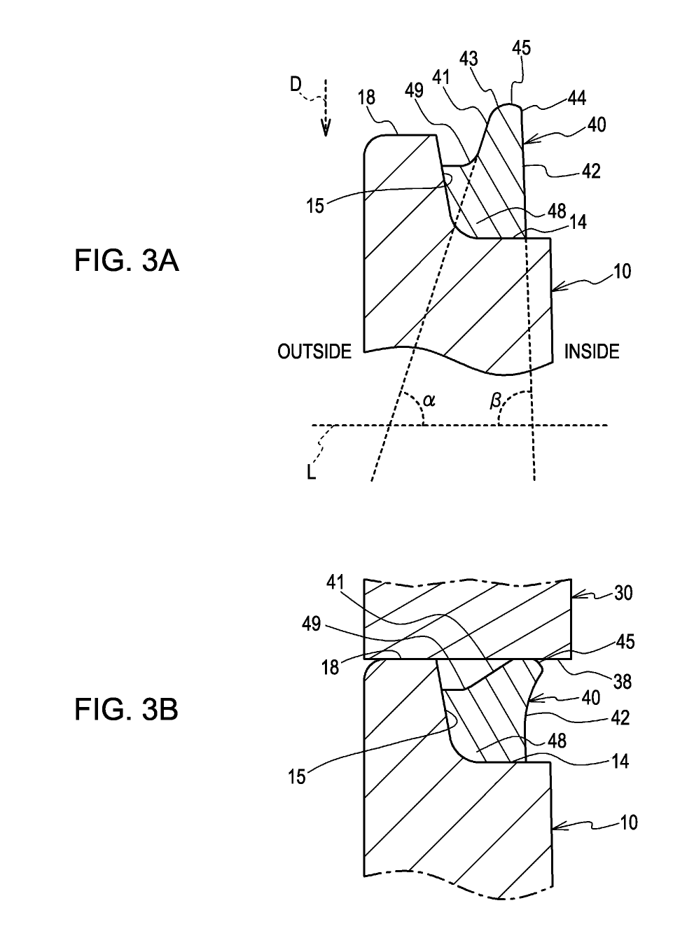

FIG. 3A is a sectional view along the line IIIA-IIIA in FIG. 2B. FIG. 3B is a view of the portion shown in FIG. 3A when the rear case 10 and the front case 30 have been joined. FIG. 3A shows the state before the rear case 10 and the front case 30 are joined. That is, FIG. 3A shows the position of the gasket 40 when the rear case 10 and the front case 30 are separate from each other.

As shown in FIG. 3A, the gasket 40 is bonded to a bonding surface 14 of the rear case 10. The gasket 40 has a projecting shape, and includes side portions 41 and 42, a top portion 45, and a bonding portion 48. The side portions 41 and 42 are on opposites sides of the top portion 45. The tip of the gasket 40 is higher than an abutment surface 18. The side portion 41 is on the outer side, and the side portion 42 is on the inner side, with respect to the rear case 10.

The side portions 41 and 42 have different inclination angles α and β, respectively. The inclination angle α is smaller than the inclination angle β. The sum of the inclination angles α and β is, for example, but not limited to, 120 degrees to 167 degrees. The inclination angles α and β are defined with respect to an imaginary line L that is perpendicular to a direction D in which the front case 30 is joined to the rear case 10. The inclination angles may be equal to or greater than 90 degrees. A recess 49 is provided on the side-portion-41 side. The recess 49 reduces the distance between the side portions 41 and 42.

A curved portion 43 is provided between the side portion 41 and the top portion 45. A curved portion 44 is provided between the side portion 42 and the top portion 45. The curved portions 43 and 44 have different radii of curvature. The radius of curvature of the curved portion 43 is smaller than that of the curved portion 44.

The bonding portion 48 is bonded to bonding surfaces 14 and 15, which are surfaces of the rear case 10. In this way, a sufficient contact area between the bonding portion 48 and the rear case 10 is obtained. However, the surface of the rear case 10 to which the gasket 40 is bonded is not limited to this form. For example, the gasket may be bonded to a curved surface that is concave as viewed from the gasket side.

As illustrated in FIG. 3B, when the rear case 10 and the front case 30 have been joined, the abutment surface 18 abuts a pressing surface 38 of the front case 30, and the gasket 40 is pressed by the pressing surface 38 and bent toward the inside of the rear case 10. The gasket 40 abuts the pressing surface 38 mainly at the side portion 41 and the top portion 45. The gasket 40 is elastic, and therefore exerts pressure on the rear case 10 and the front case 30, thereby providing water-tightness between the rear case 10 and the front case 30.

Because of the different inclination angles α and β, the gasket 40 tends to be bent toward a particular side when the rear case 10 and the front case 30 are joined. Also, because the curved portions 43 and 44 have different radii of curvature, the gasket 40 tends to be bent toward a particular side. Moreover, the recess 49 reduces the distance between the side portions 41 and 42 so that the gasket 40 is easily bent. Every part of the gasket 40, which is in the form of a ring as described above, is bent inward when the rear case 10 and the front case 30 are joined.

When the gasket 40 is bent, the contact area between the front case 30 and the gasket 40 becomes larger than when the gasket 40 is pressed by the front case 30 while remaining erect. As a result, the pressure applied to the front case 30 is reduced and the front case 30 is subjected to less stress. This allows the front case 30 to be thin. The recess 49 prevents the resilient force of the gasket 40 from being too great.

Next, a gasket whose structure is different from that of the present embodiment will be described. This gasket is not bonded to the rear case, but housed in a groove of the rear case. This gasket has a projecting shape. In order to facilitate the mounting of the gasket in the groove, the width of the groove is made larger than that of the gasket. There is a risk of the gasket becoming skewed from the desired position when the rear case and the front case are joined. If the rear case and the front case are joined in such a condition, there is a risk that the resilient force of the gasket will become less than the expected level. In that case, there is a risk that the water-tightness between the rear case and the front case will be degraded. Moreover, there is a risk of water entering through the gap between the bottom of the gasket and the rear case. If care has to be taken to maintain the gasket in a desired position when joining the front case and the rear case, there is a risk of the efficiency with which the joining operation is performed becoming degraded.

In contrast, in the present embodiment, the rear case 10 and the gasket 40 are bonded together by being molded together. Therefore, the gasket 40 is fixed in a desired position before assembly, so that it is not necessary to take care to maintain the position of the gasket 40 when joining the rear case 10 and the front case 30. Therefore, the efficiency with which the joining operation is performed is improved. When the rear case 10 and the front case 30 have been joined, the gasket 40 is bent and water-tightness is obtained.

Next, modifications will be described.

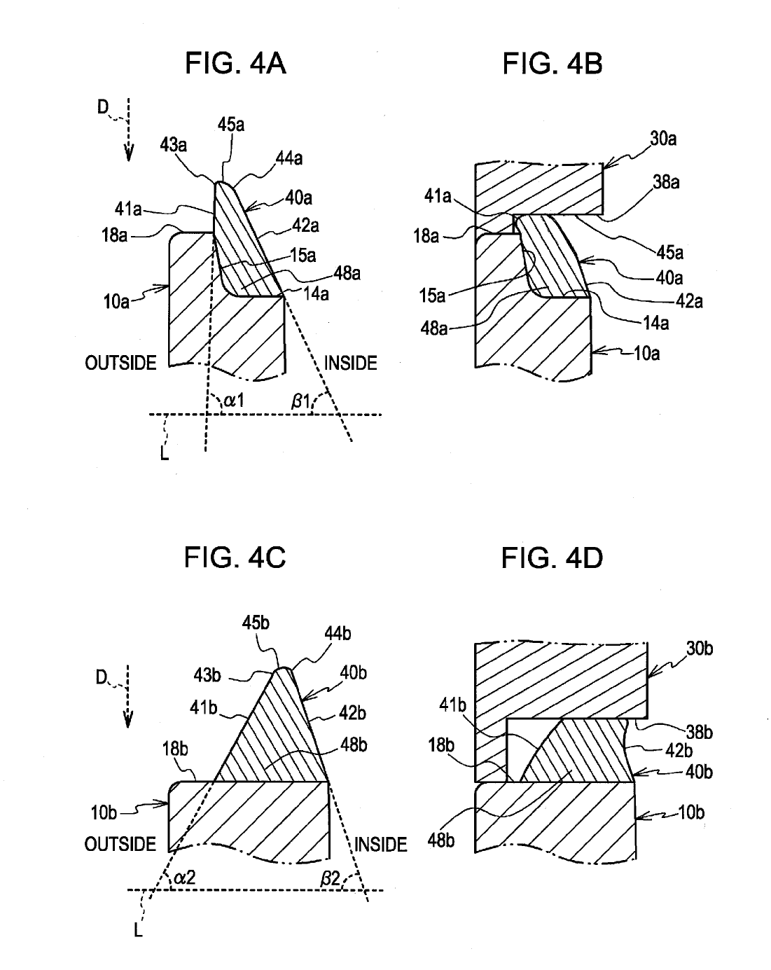

FIGS. 4A and 4B are views illustrating a first modification. FIGS. 4C and 4D are views illustrating a second modification. As illustrated in FIG. 4A, in a gasket 40a of the first modification, an inclination angle α1 of a side portion 41a is larger than an inclination angle β1 of a side portion 42a. The radius of curvature of a curved portion 43a is smaller than that of a curved portion 44a. As illustrated in FIG. 4B, after the cases have been joined, the tip of the gasket 40a is bent toward the inside. A pressing surface 38a has the form of a step. A surface of the pressing surface 38a that is perpendicular to a direction D presses the gasket 40a. The direction D is the direction in which the cases are joined. The gasket 40a of the first modification also improves the efficiency with which the joining operation is performed.

As illustrated in FIG. 4C, in a gasket 40b of the second modification, an inclination angle α2 of a side portion 41b is smaller than an inclination angle β2 of a side portion 42b. The radius of curvature of a curved portion 43b is larger than that of a curved portion 44b. A pressing surface 38b has the form of a step. A gasket 40b is bonded to an abutment surface 18b which is flat. As illustrated in FIG. 4D, after the joining, the gasket 40b is bent toward the inside. A portion of the pressing surface 38b of a front case 30b that is perpendicular to a direction D presses the gasket 40b. The direction D is the direction in which the cases are joined. As illustrated in FIG. 4D, a sufficient contact area between the front case 30b and the gasket 40b is obtained. The gasket 40b of the second modification also improves the efficiency with which the joining operation is performed.

While a preferred embodiment of the present invention has been described in detail, the present invention is not limited to the embodiment. Various modifications and changes are possible without departing from the spirit of the present invention that is set forth in the claims.

The electronic device is not limited to a cellular phone, and may be, for example, a PDA or a notebook computer. The housing in which the gasket is used may be one that houses something other than electronic components. It is only necessary that the gasket should be bent always toward a particular side, and the gasket may be so designed as to be bent toward the outside of the case. Recesses may be provided on both sides of the gasket. The gasket may be provided in the rear case 60.

All examples and conditional language recited herein are intended for pedagogical purposes to aid the reader in understanding the invention and the concepts contributed by the inventor to furthering the art, and are to be construed as being without limitation to such specifically recited examples and condition, nor does the organization of such examples in the specification relate to a showing of superiority and inferiority of the invention. Although the embodiment of the present inventions have been described in detail, it should be understood that the various changes, substitutions, and alternations could be made hereto without departing from the spirit and scope of the invention.

What is claimed is:

1. An electronic device comprising:
a first case and a second case;
a gasket sandwiched between the first case and the second case, the gasket having an elasticity and being formed on the edge of the first case; and
an electronic component accommodated in the first and second cases;
wherein the gasket has a first side surface facing inward and a second side surface facing outward, and the first side surface has a first angle with respect to an imaginary line which is perpendicular to a direction in which the first case is joined to the second case, the second side surface has the second angle with respect to an imaginary line which is perpendicular to a direction in which the first case is joined to the second case, and the first angle is different from the second angle when the first case is disjoined to the second case.

2. The electronic device according to claim 1, wherein the gasket has a top portion, a first curved portion which is provided between the first side surface and the top portion, a second curved portion which is provided between the second side surface and the top portion, and the first curved portion and the second curved portion have different radii of curvature when the first case is disjoined to the second case

3. The electronic device according to claim 1, wherein at least one of the first and second side surfaces of the gasket has a recess.

4. The electronic device according to claim 1, wherein the gasket is molded together with the first case.

5. The electronic device according to claim 1, wherein the gasket is bent toward the inside of the first case by a pressure pressed by the second case when the first case is joined to the second case.

6. The electronic device according to claim 2, wherein the first angle is smaller than the second angle, and the first radius of curvature of the first curved portion is larger than the second radius of curvature of the second curved portion.

7. The electronic device according to claim 1, wherein the gasket has a bonding portion bonded to a curved plane which is concave to two planes continued the first case or the gasket.

8. A housing comprising:
a first case and a second case; and
a gasket sandwiched between the first case and the second case, the gasket having an elasticity;
wherein the gasket has a first side surface facing inward and a second side surface facing outward, and the first side surface has a first angle with respect to an imaginary line which is perpendicular to a direction in which the first case is joined to the second case, the second side surface has the second angle with respect to an imaginary line which is perpendicular to a direction in which the first case is joined to the second case, and the first angle is different from the second angle when the first case is disjoined to the second case.

9. A gasket sandwiched between a first case and a second case, the gasket having an elasticity comprising:
a top portion;
a first side surface facing inward and a second side surface facing outward; and
a bonding portion bonded to the first case;
wherein the first side surface has a first angle with respect to an imaginary line which is perpendicular to a direction in which the first case is joined to the second case, the second side surface has the second angle with respect to an imaginary line which is perpendicular to a direction in which the first case is joined to the second case, and the first angle is different from the second angle when the first case is disjoined to the second case.
